(19) United States
(12) Patent Application Publication
(10) Pub. No.: US 2023/0047026 A1
(43) Pub. Date: Feb. 16, 2023

(54) SEMICONDUCTOR PACKAGE

(71) Applicant: Samsung Electronics Co., Ltd., Suwon-si (KR)

(72) Inventors: Seung Soo HA, Seongnam-si (KR); Ju-Youn CHOI, Hwaseong-si (KR); In Won O, Hwaseong-si (KR); Jun Ho LEE, Suwon-si (KR)

(21) Appl. No.: 17/867,764

(22) Filed: Jul. 19, 2022

(30) Foreign Application Priority Data
Aug. 10, 2021 (KR) 10-2021-0105127

(51) Int. Cl. H01L 23/498; H01L 25/16

(52) U.S. Cl. CPC H01L 23/49838; H01L 25/162; H01L 23/49816; H01L 23/49822; H01L 23/49833; H01L 24/08

(57) ABSTRACT

A semiconductor package includes: a first wiring structure including a first wiring layer, and a second wiring layer disposed on the first wiring layer, and connected to a first connecting structure placed disposed on the first wiring layer; a first semiconductor chip disposed on the first wiring structure and connected to the first wiring structure through a first connecting pad disposed on a first side of the first semiconductor chip; a second wiring structure disposed on the first semiconductor chip; and an insulating member disposed between the first and second wiring structures, wherein the first wiring structure further includes a first signal pattern that is electrically connected to the first connecting pad, and the first signal pattern redistributes the first connecting pad to the first connecting structure via the insulating member.

### CROSS-REFERENCE TO RELATED APPLICATION

This application claims priority under 35 U.S.C. § 119 to Korean Patent Application No. 10-2021-0105127 filed on Aug. 10, 2021 in the Korean Intellectual Property Office, the disclosure of which is incorporated by reference herein in its entirety.

### TECHNICAL FIELD

The present inventive concept relates to a semiconductor package, and more particularly to, a semiconductor package including a signal pattern.

### DISCUSSION OF THE RELATED ART

In recent years, with the increased development of smart electronic devices, specifications of the components used for them have also increased. For example, specifications of application processors (AP), which are core chips of the smart electronic devices, have rapidly developed. In addition, the AP, which is a component of the smart device, has recently been packaged in various ways.

With the development of such an electronic industry for smart electronic devices, there has been an increased demand for higher functionality, higher speed, and smaller size of electronic components. A method of stacking and mounting multiple semiconductor chips on a single package wiring structure, or a method of stacking the package on the package may be used to the growing demands. For example, a package-in-package (PIP) type semiconductor package or a package-on-package (POP) type semiconductor package may be used.

### SUMMARY

According to an exemplary embodiment of the present inventive concept, a semiconductor package includes: a first wiring structure including a first wiring layer, and a second wiring layer disposed on the first wiring layer, and connected to a first connecting structure placed disposed on the first wiring layer; a first semiconductor chip disposed on the first wiring structure and connected to the first wiring structure through a first connecting pad disposed on a first side of the first semiconductor chip; a second wiring structure disposed on the first semiconductor chip; and an insulating member disposed between the first and second wiring structures, wherein the first wiring structure further includes a first signal pattern that is electrically connected to the first connecting pad, and the first signal pattern redistributes the first connecting pad to the first connecting structure via the insulating member.

According to an exemplary embodiment of the present inventive concept, a semiconductor package includes: a first wiring structure including a first wiring layer and a second wiring layer disposed on the first wiring layer, and connected to a first connecting structure disposed below the first wiring layer; a first semiconductor chip disposed on the first wiring structure and connected to the first wiring structure through a first connecting pad disposed on a first side of the first semiconductor chip; a second wiring structure disposed on the first semiconductor chip; and a mold layer disposed between the first and second wiring structures, wherein the first wiring structure includes a first signal pattern that is electrically connected to the first connecting pad, and the first signal pattern redistributes the first connecting pad to the first connecting structure via the mold layer and the second wiring structure.

According to an exemplary embodiment of the present inventive concept, a semiconductor package includes: a first semiconductor package; and a second semiconductor package disposed on the first semiconductor package, wherein the first semiconductor package includes: a first wiring structure including a first wiring layer and a second wiring layer disposed on the first wiring layer, and connected to a first connecting structure disposed below the first wiring layer; a first semiconductor chip disposed on the first wiring structure and connected to the first wiring structure through a first connecting pad disposed on a first side of the first semiconductor chip; a second wiring structure disposed on the first semiconductor chip; and an insulating member disposed between the first and second wiring structures and including a connecting via, wherein the first wiring structure includes a first signal pattern electrically connected to the first connecting pad, the first signal pattern redistributes the first connecting pad to the first connecting structure via the connecting via, and the second semiconductor package includes a second semiconductor chip mounted on a third wiring structure that is disposed on the first semiconductor package.

### BRIEF DESCRIPTION OF THE DRAWINGS

The above and other features of the present inventive concept will become more apparent by describing in detail exemplary embodiments thereof, with reference to the attached drawings, in which:

FIGS. 1 and 2 are diagrams illustrating an electronic device according to an exemplary embodiment of the present inventive concept;

FIG. 3 is a diagram illustrating a semiconductor package and a main board of FIG. 2;

FIG. 4 is a layout diagram of the semiconductor package of FIG. 3 according to an exemplary embodiment of the present inventive concept;

FIG. 5 is an enlarged view of a region R of FIG. 4 from a plan view;

FIG. 6 is a schematic cross-sectional view of the semiconductor package taken along I-I′ of FIG. 4, according to an exemplary embodiment of the present inventive concept;

FIG. 7 is a cross-sectional view in which the region R of FIG. 4 is taken along I-I′ of FIG. 4;

FIGS. 8, 9 and 10 are diagrams illustrating a wiring layer of a first wiring structure of the region R of FIG. 4;

FIG. 11 is a diagram illustrating a wiring layer of an insulating member of the region R of FIG. 4;

FIG. 12 is a schematic cross-sectional view of a semiconductor package taken along I-I′ of FIG. 4, according to an exemplary embodiment of the present inventive concept;

FIG. 13 is a schematic cross-sectional view of a semiconductor package taken along I-I′ of FIG. 4, according to an exemplary embodiment of the present inventive concept;

FIG. 14 is a schematic cross-sectional view of a semiconductor package taken along I-I′ of FIG. 4, according to an exemplary embodiment of the present inventive concept;

FIG. 15 is a schematic cross-sectional view of a semiconductor package taken along I-I′ of FIG. 4, according to an exemplary embodiment of the present inventive concept; and

FIG. 16 is a schematic cross-sectional view of a semiconductor package taken along I-I′ of FIG. 4, according to an exemplary embodiment of the present inventive concept.

### DETAILED DESCRIPTION OF THE EMBODIMENTS

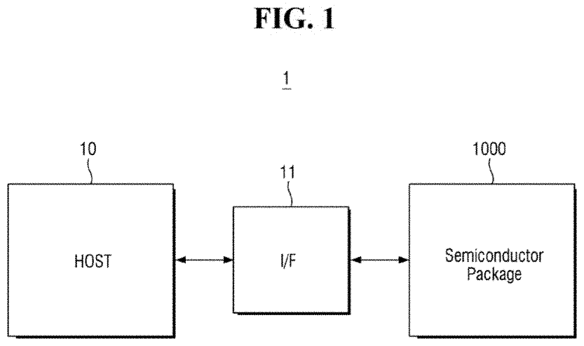

Hereinafter, a semiconductor package according to an exemplary embodiment of the present inventive concept will be described with reference to FIGS. 1 to 11.

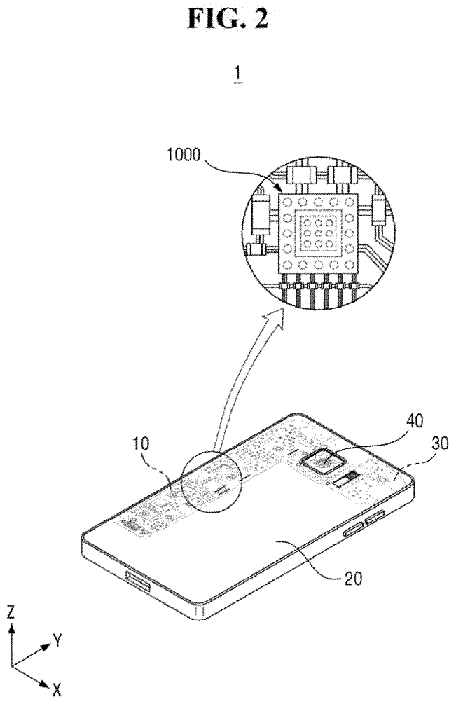

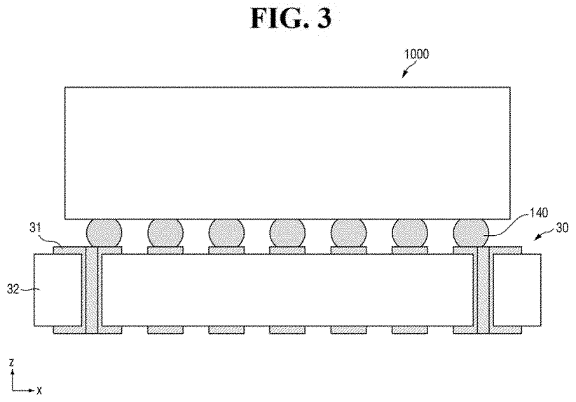

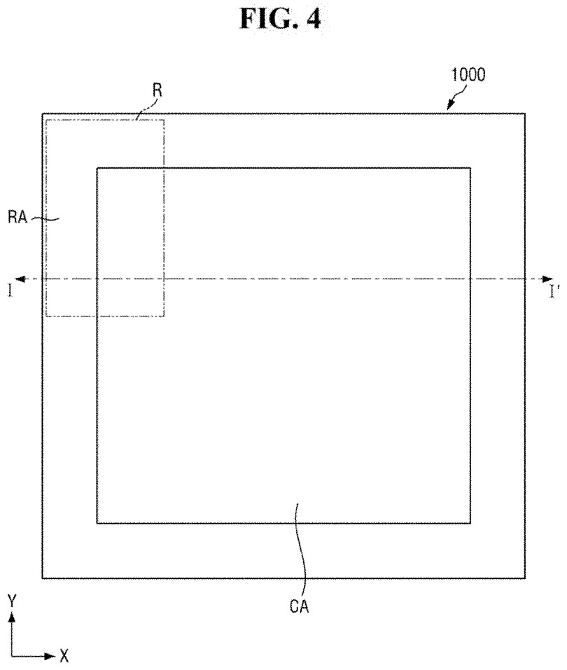

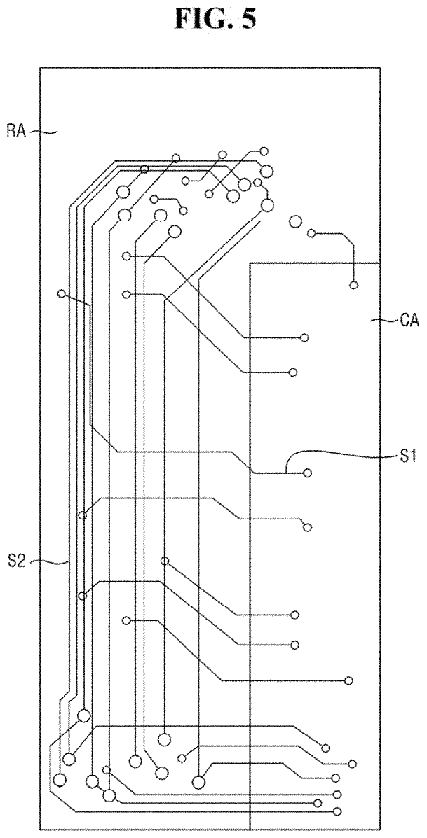

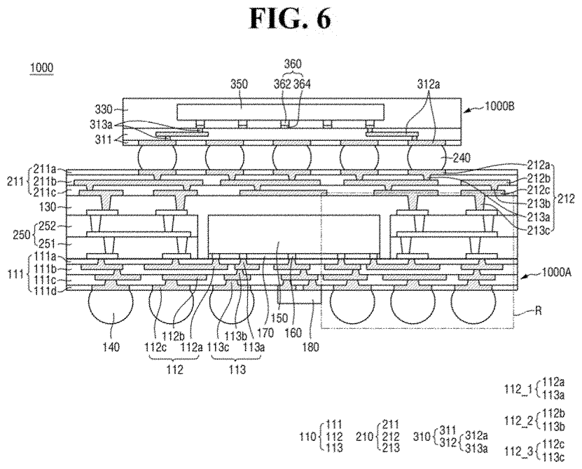

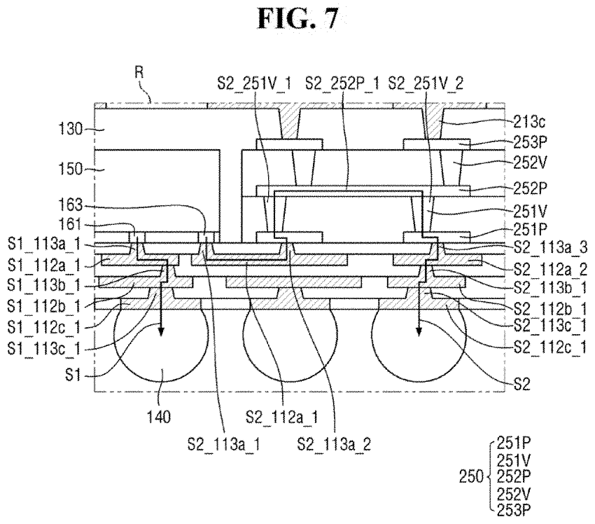

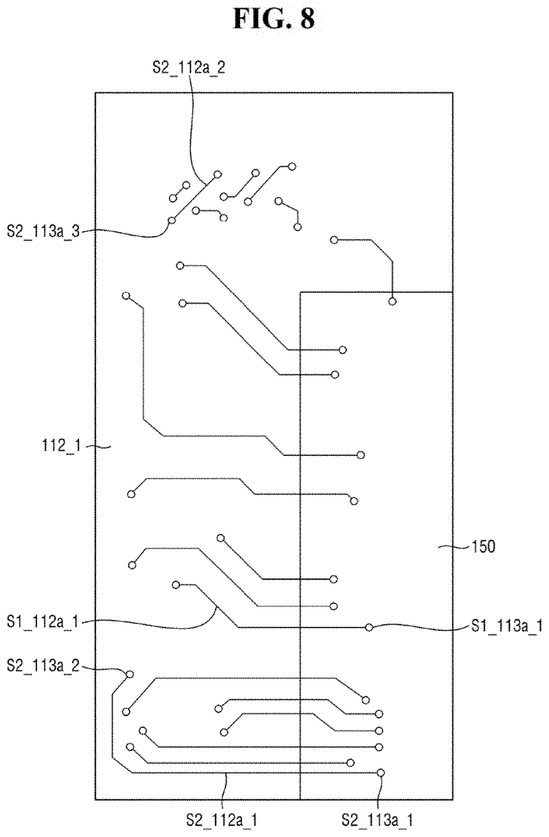

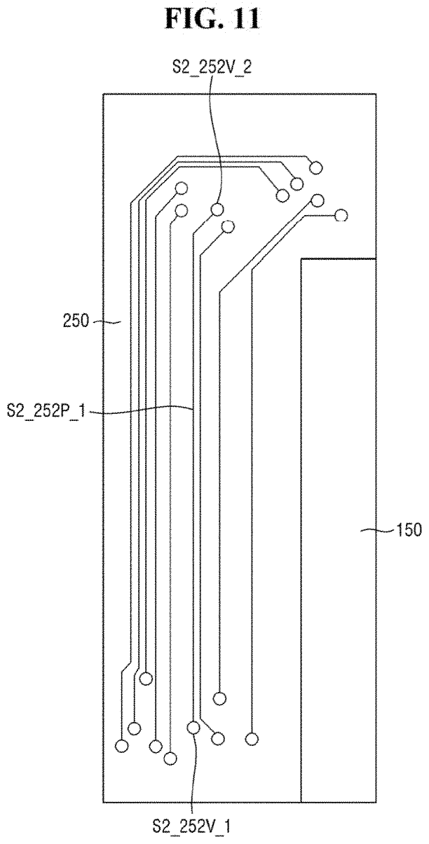

FIGS. 1 and 2 are diagrams illustrating an electronic device according to an exemplary embodiment of the present inventive concept. FIG. 3 is a diagram illustrating a semiconductor package and a main board of FIG. 2. FIG. 4 is a layout diagram of the semiconductor package of FIG. 3 according to an exemplary embodiment of the present inventive concept. FIG. 5 is an enlarged view of a region R of FIG. 4 from a plan view. FIG. 6 is a schematic cross-sectional view of the semiconductor package taken along I-I′ of FIG. 4, according to an exemplary embodiment of the present inventive concept. FIG. 7 is a cross-sectional view in which the region R of FIG. 4 is taken along I-I′ of FIG. 4. FIGS. 8 to 10 are diagrams illustrating a wiring layer of a first wiring structure of the region R of FIG. 4. FIG. 11 is a diagram illustrating a wiring layer of an insulating member of the region R of FIG. 4.

Referring to FIG. 1, the electronic device 1 may include a host 10, an interface 11, and a semiconductor package 1000.

In an exemplary embodiment of the present inventive concept, the host 10 may be connected to the semiconductor package 1000 through an interface 11. For example, the host 10 may transmit a signal to the semiconductor package 1000 to control the semiconductor package 1000. Further, for example, the host 10 may receive a signal from the semiconductor package 1000 and process the data included in the signal.

For example, the host 10 may include a central processing unit (CPU), a controller, an application specific integrated circuit (ASIC), and the like. Further, for example, the host 10 may include memory chips such as a DRAM (Dynamic Random Access Memory), a SRAM (Static RAM), a PRAM (Phase-change RAM), a MRAM (Magneto resistive RAM), a FeRAM (Ferroelectric RAM), and a RRAM (Resistive RAM).

Referring to FIGS. 1 and 2, the electronic device 1 may include a host 10, a body 20, a main board 30, a camera module 40, and a semiconductor package 1000.

The main board 30 may be mounted inside the body 20 of the electronic device 1. The host 10, the camera module 40, and the semiconductor package 1000 may be mounted on the main board 30. The host 10, the camera module 40, and the semiconductor package 1000 may be electrically connected to each other by the main board 30. For example, the interface 11 may be mounted by the main board 30.

The host 10 and the semiconductor package 1000 may be electrically connected to each other by the main board 30 such that signals may be transmitted between the host 10 and the semiconductor package 1000.

Referring to FIG. 3, the semiconductor package 1000 may be placed on the main board 30. For example, a first connecting structure 140 may be placed on the main board 30. The main board 30 may be connected to the semiconductor package 1000 through the first connecting structure 140.

The main board 30 may be, for example, a printed circuit wiring structure (Printed Circuit Board: PCB), a ceramic wiring structure, a glass wiring structure, an interposer wiring structure, or the like. However, the present inventive concept is not limited thereto, and as an example, the main board 30 is a printed circuit wiring structure for the purpose of this description.

The main board 30 may include a connecting structure 31 and a core 32. The core 32 may include, for example, a CCL (Copper Clad Laminate), a photoplethysmogram (PPG), an ABF (Ajinomoto Build-up Film), epoxy, polyimide and the like. For example, the connecting structure 31 may include, but is not limited to, at least one of copper (Cu), aluminum (Al), silver (Ag), tin (Sn), gold (Au), nickel (Ni), lead (Pb), titanium (Ti), and alloys thereof.

The core 32 is placed at the center of the main board 30, and the connecting structure 31 may be placed above and below the core 32. The connecting structure 31 may be placed to be exposed above and below the main board 30. For example, the wiring structure 31 may extend along the side surfaces of the core 32.

Further, the connecting structure 31 may be placed to penetrate the core 32. The connecting structure 31 may electrically connect to elements that come into contact with the main board 30. For example, the connecting structure 31 may electrically connect the semiconductor package 1000 and the host 10 to each other. For example, the connecting structure 31 may electrically connect the semiconductor package 1000 and the host 10 through the first connecting structure 140.

Referring to FIGS. 4 and 5, the semiconductor package 1000 may include a chip area CA, and a routing area RA formed around the chip area CA. A first semiconductor chip 150 to be described below may be formed in the chip area CA, and a first connecting structure 140 to be described below may be formed in the routing area RA.

Referring to FIG. 5, first and second signal patterns S1 and S2 may form an electrical path from the first semiconductor chip 150, in the chip area CA, toward the first connecting structure 140, in the routing area RA. The second signal pattern S2 may form an electrical path from the first semiconductor chip 150 toward the first connecting structure 140 via an insulating member 250.

Referring to FIG. 6, the semiconductor package according to an exemplary embodiment of the present inventive concept includes a first wiring structure 110, a first semiconductor chip 150, a second wiring structure 210, and an insulating member 250.

The first wiring structure 110 may be a wiring structure for packaging. For example, the first wiring structure 110 may be a printed circuit wiring structure (e.g., a printed circuit board (PCB)), a ceramic wiring structure, or the like. In addition, the first wiring structure 110 may be a wiring structure for a wafer level package (WLP) fabricated at a wafer level. The first wiring structure 110 may include a lower side and an upper side opposite to each other.

The first wiring structure 110 includes an insulating layer 111 and a wiring layer 112. The insulating layer 111 of the first wiring structure 110 may include a first insulating layer 111a, a second insulating layer 111b, a third insulating layer 111c and a fourth insulating layer 111d which are sequentially placed between the first semiconductor chip 150 and the first connecting structure 140.

A first wiring layer 112_1 of the first wiring structure 110 may include a first wiring pad 112a and a first wiring via 113a which are sequentially placed between the first semiconductor chip 150 and the first connecting structure 140. The second wiring layer 112_2 of the first wiring structure 110 may include a second wiring pad 112b and a second wiring via 113b, each of which are placed below the first wiring layer 112_1. A third wiring layer 112_3 of the first wiring structure 110 may include a third wiring pad 112c and a third wiring via 113c, each of which are placed below the second wiring layer 112_2.

The insulating layer 111 of the first wiring structure 110 may include, for example, a printed circuit board (PCB) or a ceramic substrate. However, the present invention is not limited thereto.

When the insulating layer 111 is a printed circuit board, the insulating layer 111 may be made of at least one of phenol resin, epoxy resin, and/or polyimide. For example, the insulating layer 111 may include at least one of ABF (Ajinomoto Build-up Film), FR-4, tetrafunctional epoxy, polyphenylene ether, epoxy/polyphenyl oxide, BT (bismaleimide triazine), thermount, cyanate ester, polyimide, and/or liquid crystal polymer.

In an exemplary embodiment of the present inventive concept, a surface of the insulating layer 111 may be covered with a solder resist. In an exemplary embodiment of the present inventive concept, a fourth insulating layer 111d may be a solder resist. However, the present inventive concept is not limited thereto.

The fourth insulating layer 111d may include, for example, but is not limited to, a photoimageable dielectric (PID).

In an exemplary embodiment of the present inventive concept, although the insulating layer 111 and the wiring layer 112 of the first wiring structure 110 are each shown as four and three layers, this is merely an example, and the number of layers of the insulating layer 111 and the wiring layer 112 is not limited thereto.

In an exemplary embodiment of the present inventive concept, a first connecting structure 140 may be formed on the lower side of the first wiring structure 110. The first connecting structure 140 may be connected to the third wiring pad 112c. The first connecting structure 140 may have, for example, but is not limited thereto, a spherical shape or an elliptical spherical shape. Although the first connecting structure 140 may include, for example, at least one of tin (Sn), indium (In), lead (Pb), zinc (Zn), nickel (Ni), gold (Au), silver (Ag), copper (Cu), antimony (Sb), bismuth (Bi), and combinations thereof, the present inventive concept is not limited thereto.

The first connecting structure 140 may electrically connect the first wiring structure 110 to an external device. Accordingly, the first connecting structure 140 may provide an electrical signal to the first wiring structure 110, and/or may provide an electrical signal, which is provided from the first wiring structure 110, to an external device.

The first insulating layer 111a and the fourth insulating layer 111d are formed at the uppermost part and the lowermost part of the insulating layer 111, respectively. For example, an upper surface of the first insulating layer 111a may be an upper surface of the insulating layer 111, and a lower surface of the fourth insulating layer 111d may be a lower surface of the insulating layer 111. The first insulating layer 111a may cover the upper side of the second insulating layer 111b and expose the first wiring via 113a. The fourth insulating layer 111d may cover the lower side of the third insulating layer 111c and expose the third wiring pad 112c.

In an exemplary embodiment of the present inventive concept, the first wiring pad 112a may be electrically connected to the third wiring pad 112c. For example, the first wiring pad 112a may be electrically connected to the third wiring pad 112c, by being connected to the second wiring via 113b, the second wiring pad 112b, and the third wiring via 113c.

The first semiconductor chip 150 may be placed on the first wiring structure 110. For example, the first semiconductor chip 150 may be mounted on the upper side of the first wiring structure 110. For example, the first semiconductor chip 150 may be an integrated circuit (IC) in which hundreds to millions or more of semiconductor elements are integrated therein. For example, the first semiconductor chip 150 may be, but is not limited to, an application processor (AP) such as a CPU (Central Processing Unit), a GPU (Graphic Processing Unit), an FPGA (Field-Programmable Gate Array), a digital signal processor, an encryption processor, a micro processor, and a micro controller. For example, the first semiconductor chip 150 may be a logic chip such as an ADC (Analog-Digital Converter) and an ASIC (Application-Specific IC), and may be a memory chip such as a volatile memory (e.g., a DRAM) and a non-volatile memory (e.g., a ROM, a flash memory). For example, the first semiconductor chip 150 may be configured by combining these elements with each other.

Although only one first semiconductor chip 150 is shown as being formed on the first wiring structure 110, this is merely an example, and the present inventive concept is not limited thereto. For example, a plurality of first semiconductor chips 150 may be formed side by side on the first wiring structure 110, or a plurality of first semiconductor chips 150 may be sequentially stacked on each other on the first wiring structure 110.

In an exemplary embodiment of the present inventive concept, the first semiconductor chip 150 may be mounted on the first wiring structure 110 by a flip chip bonding method. For example, at least one or more connecting pads 160 may be formed between the upper side of the first wiring structure 110 and the lower side of the first semiconductor chip 150. The connecting pad 160 may electrically connect the first wiring structure 110 and the first semiconductor chip 150 to each other. As will be described later, the connecting pad 160 may include a first connecting pad 161 connected to a first signal pattern S1, and a second connecting pad 163 connected to a second signal pattern S2.

The connecting pad 160 may protrude from the lower side of the first semiconductor chip 150. The connecting pad 160 may include, for example, but is not limited to, copper (Cu), copper alloys, nickel (Ni), palladium (Pd), platinum (Pt), gold (Au), cobalt (Co), and combinations thereof.

A passivation film 170 that exposes the connecting pad 160 may be formed on the lower side of the first semiconductor chip 150. The passivation film 170 may be, for example, an oxide film, a nitride film, or the like. In addition, the passivation film 170 may be a double layer of the oxide film and the nitride film.

The second wiring structure 210 may be interposed between the first wiring structure 110 and the third wiring structure 310. For example, the second wiring structure 210 may be placed on the first wiring structure 110 and the first semiconductor chip 150. In an exemplary embodiment of the present inventive concept, the second wiring structure 210 may be an interposer. The second wiring structure 210 may facilitate the connection between the first wiring structure 110 and the third wiring structure 310. Further, the second wiring structure 210 may prevent a warpage phenomenon between the first wiring structure 110 and the third wiring structure 310.

The second wiring structure 210 may include, for example, a printed circuit board (PCB) or a ceramic substrate. However, the present inventive concept is not limited thereto. In an exemplary embodiment of the present inventive concept, the second wiring structure 210 may include silicon (Si).

The second wiring structure 210 may include a lower side and an upper side opposite to each other. For example, the lower side of the second wiring structure 210 may face the upper side of the first wiring structure 110, and the upper side of the second wiring structure 210 may face a lower side of a third wiring structure 310 to be described below.

The second wiring structure 210 may be spaced apart from the first wiring structure 110. Further, the second wiring structure 210 may be spaced apart from the first semiconductor chip 150. For example, the second wiring structure 210 may be disposed above the first semiconductor chip 150.

The second wiring structure 210 includes an insulating layer 211 and a wiring layer 212. The insulating layer 211 of the second wiring structure 210 may include a first insulating layer 211a, a second insulating layer 211b and a third insulating layer 211c which are sequentially placed between the second connecting structure 240 and the insulating member 250, which will be described later.

The wiring layer 212 of the second wiring structure 210 may include a first wiring pad 212a, a second wiring pad 212b, and a third wiring pad 212c that are sequentially placed between the second connecting structure 240 and the insulating member 250, which will be described below. The wiring layer 212 of the second wiring structure 210 may include a third wiring via 213c that connects the insulating member 250 and the third wiring pad 212c to each other. The wiring layer 212 further includes a second wiring via 213b that connects the third wiring pad 212c and the second wiring pad 212b to each other. In addition, the wiring layer 212 further includes a first wiring via 213a that connects the first wiring pad 212a and the second wiring pad 212b to each other.

In an exemplary embodiment of the present inventive concept, although the insulating layer 211 and the wiring layer 212 are each shown as three layers, this is merely an example, and the number of layers of the insulating layer 211 and the wiring layer 212 is not limited thereto.

The first insulating layer 211a and the third insulating layer 211c are formed at the uppermost part and the lowermost part of the insulating layer 211, respectively. For example, an upper surface of the first insulating layer 211a may be an upper surface of the insulating layer 211, and a lower surface of the third insulating layer 211c may be a lower surface of the insulating layer 211. The first insulating layer 211a may cover the upper side of the second insulating layer 211b and expose the first wiring pad 212a. The third insulating layer 211c may cover the lower side of the second insulating layer 211b and expose the second wiring pad 212b. For example, the third insulating layer 211c may expose the third wiring pad 212c.

A surface of the insulating layer 211 may be covered with a solder resist. In an exemplary embodiment of the present inventive concept, the first insulating layer 211a may be a solder resist. However, the present inventive concept is not limited thereto.

The first insulating layer 211a may include, for example, but is not limited to, a photoimageable dielectric (PID).

In an exemplary embodiment of the present inventive concept, the first wiring pad 212a may be electrically connected to the insulating member 250 to be described below. For example, the first wiring pad 212a may be electrically connected to the insulating member 250, by being connected to the first wiring via 213a, the second wiring pad 212b, the second wiring via 213b, the third wiring pad 212c, and the third wiring via 213c.

The insulating member 250 may electrically connect the first and second wiring structures 110 and 210 to each other. The insulating member 250 may include a second mold layer 251, a third mold layer 252, first and second connecting vias 251V and 252V, and first to third connecting pads 251P, 252P and 253P, between the first wiring structure 110 and the second wiring structure 210.

The second mold layer 251 may be placed on the upper side of the first wiring structure 110. The second mold layer 251 may be placed to surround the first semiconductor chip 150. For example, the second mold layer 251 may be placed to at least partially surround the side wall of the first semiconductor chip 150. The second mold layer 251 may be spaced apart from the side wall of the first semiconductor chip 150. In an exemplary embodiment of the present inventive concept, the second mold layer 251 may contact the first semiconductor chip 150.

The third mold layer 252 may be placed on the second mold layer 251. The third mold layer 252 may be placed to surround the first semiconductor chip 150. For example, the third mold layer 252 may be placed to at least partially surround the side wall of the first semiconductor chip 150. The third mold layer 252 may be spaced apart from the side wall of the first semiconductor chip 150. In an exemplary embodiment of the present inventive concept, the third mold layer 252 may contact the first semiconductor chip 150.

Each of the second mold layer 251 and the third mold layer 252 may include an insulating material. For example, each of the second and third mold layers 251 and 252 may be insulating members such as an embedded trace substrate (ETS). In addition, for example, the second and third mold layers 251 and 252 may be insulating members having a core. Each of the second mold layer 251 and the third mold layer 252 may include a material different from that of the first mold layer 130 to be described below. However, the present inventive concept is not limited thereto.

A first connecting pad 251P may be placed on the lower side of the second mold layer 251. A second connecting pad 252P may be placed on the lower side of the third mold layer 252. A third connecting pad 253P may be placed between the second connecting via 252V and the third wiring via 213c of the second wiring structure 210. The first to third connecting pads 251P, 252P and 253P and the first and second connecting vias 251V and 252V may include conductive materials.

The first connecting via 251V may penetrate the second mold layer 251. The first connecting via 251V may be connected to each of the first connecting pad 251P and the second connecting pad 252P. The second connecting via 252V may penetrate the third mold layer 252. The second via 252V may be connected to each of the second connecting pad 252P and the third connecting pad 253P.

The second wiring structure 210 may be electrically connected to the first wiring structure 110 through the first and second connecting vias 251V and 252V, and the first to third connecting pads 251P, 252P and 253P.

Referring to FIG. 7, the first wiring structure 110 may include a first signal pattern S1 that is electrically connected to the first connecting pad 161.

In an exemplary embodiment of the present inventive concept, the first signal pattern S1 may be a high speed interface (HIS) signal. The first signal pattern S1 may be, for example, a PCIE (peripheral component interconnect express), a USB (universal serial bus), a UFS (universal flash storage), a MIPI (mobile industry processor interface), or the like. As a result, the first signal pattern S1 may mediate a communication method such as PCIE, USB, UFS and MIPI between peripheral devices and may exchange signals commands (or data).

The first signal pattern S1 may redistribute the first connecting pad 161 to the first connecting structure 140 through an electrical path that goes to the first wiring layer 112_1, the second wiring layer 112_2, and the third wiring layer 112_3 in order from the first connecting pad 161. The first connecting pad 161 may be connected to the first connecting structure 140 through a first wiring via S1_113a_1, a first wiring pad S1_112a_1, second wiring via S1_113b_1, second wiring pad S1_112b_1, a third wiring via S1_113c_1 and third wiring pad S1_112c_1.

In an exemplary embodiment of the present inventive concept, the first and second wiring layers 112_1 and 112_2 through which the first signal pattern S1 is formed may be formed by a ground plane. In this case, the first and second wiring layers 112_1 and 112_2 may function as a shielding layer. As a result, the interference of the high-speed interface signal pattern HSI received by other signals may be reduced.

Referring to FIG. 7, the first wiring structure 110 may further include a second signal pattern S2 having a different path from that of the first signal pattern S1. The first signal pattern S1 and the second signal pattern S2 may form electrical paths independent of each other. The second signal pattern S2 may be a general signal pattern other than a high-speed signal pattern. The second signal pattern S2 may be, for example, a power/ground signal pattern.

The second signal pattern S2 is electrically connected to the second connecting pad 163 placed on one side of the first semiconductor chip 150, and may redistribute the second connecting pad 163 to the first connecting structure 140.

The second signal pattern S2 may redistribute the second connecting pad 163 to the first connecting structure 140 via the insulating member 250. For example, the second signal pattern S2 may form an electrical path that goes through the wiring layer 112 and the insulating member 250.

The second signal pattern S2 may redistribute the second connecting pad 163 to the first connecting structure 140 through an electrical path that goes through the first wiring via 113a, the first wiring pad 112a, the first wiring via 113a, the first connecting pad 251P, the first connecting via 251V, the second connecting pad 252P, the first connecting via 251V, the first connecting pad 251P, the first wiring via 113a, the first wiring pad 112a, the second wiring layer 112_2, and the third wiring layer 112_3 in order from the second connecting pad 163. The second connecting pad 163 may be connected to the first connecting structure 140 through a second wiring via S2_113a_3, a second wiring pad S2_112a_2, second wiring via S2_113b_1, second wiring pad S2_112b_1, a third wiring via S2_113c_1 and third wiring pad S2_112c_1.

The second signal pattern S2 may have an electrical path which increases by a distance corresponding to the thickness of the insulating member 250 as compared with that of the first signal pattern S1. Referring to FIG. 7, the second signal pattern S2 may have an electrical path which increases by a distance corresponding to the thickness of the first connecting pad 251P, the first connecting via 251V, and the second connecting pad 252P as compared with that of the first signal pattern S1.

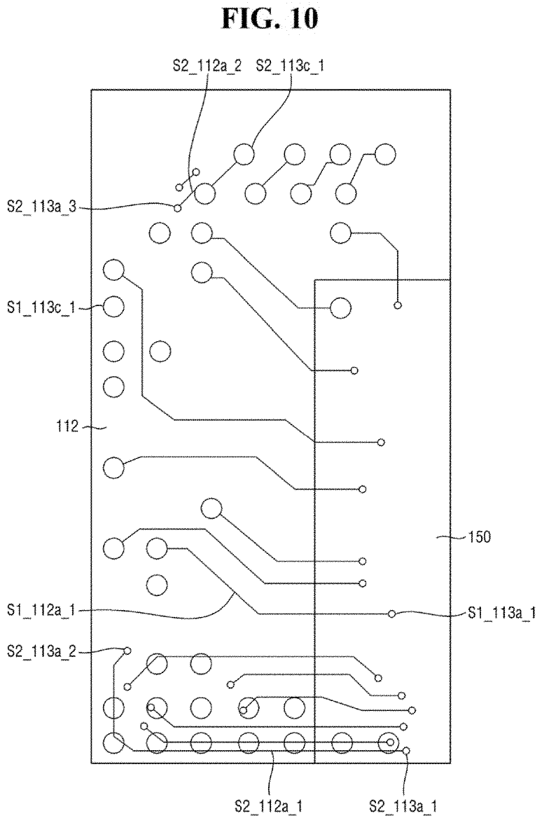

Referring to FIGS. 8 and 10, in the first wiring layer 112_1, the first signal pattern S1 transmits a signal from the first semiconductor chip 150 to a first wiring pad S1_112a_1 through a first wiring via S1_113a_1.

Referring to FIGS. 8 and 10, in the first wiring layer 112_1, the second signal pattern S2 transmits the signal from the first semiconductor chip 150 to a first wiring pad S2_112a_1 through a first wiring via S2_113a_1. After that, the second signal pattern S2 transmits the signal from the first wiring pad S2_112a_1 to the second wiring via S2_113a_2. After that, the second signal pattern S2 transmits the signal from the second wiring via S2_113a_2 to the insulating member 250 on the first wiring layer 1121. After that, the second signal pattern S2 transmits the signal, which is transmitted through the insulating member 250, to a first wiring pad S2_112a_2 through a first wiring via S2_113a_3.

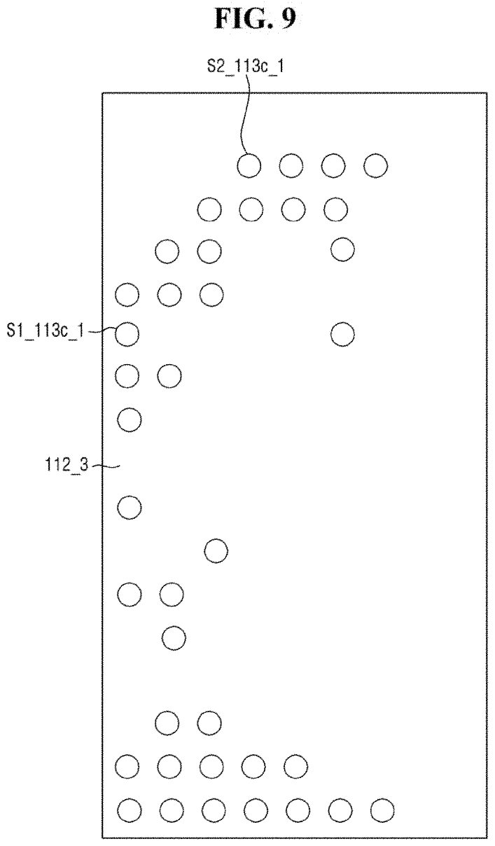

Referring to FIGS. 9 and 10, in the third wiring layer 112_3, the first signal pattern S1 transmits the signal, which is transmitted from the first wiring pad S1_112a_1 to the second wiring layer 112_2, to the first connecting structure 140 through a third wiring via S1_113c_1.

Referring to FIGS. 9 and 10, in the third wiring layer 112_3, the second signal pattern S2 transmits the signal, which is transmitted from the first wiring via S2_113a_3 and the first wiring pad S2_112a_2 via the second wiring layer 112_2, to the first connecting structure 140 through a third wiring via S2_113c_1.

Referring to FIG. 11, in the insulating member 250, the second signal pattern S2 transmits the signal from the second wiring via S2_113a_2 of the first wiring layer 112_1 to a second connecting pad S2_252P_1 through the first connecting pad 251P and the first connecting via S2_251V_1. The second signal pattern S2 transmits the signal to the first connecting via S2_251V_2 through the second connecting pad S2_252P_1.

For example, unlike the first signal pattern S1, the second signal pattern S2 may transmit the signal from the first semiconductor chip 150 to the first connecting structure 140 via the insulating member 250. As a result, the interference of the high-speed interface signal pattern (HIS) received by other signals may be reduced, and the routing area RA may be effectively utilized. In addition, the size of the semiconductor package may be reduced.

A first element 180 may be electrically connected to the first semiconductor chip 150 through the first wiring structure 110. The first element 180 may be electrically connected to the connecting pad 160 of the first semiconductor chip 150 through the wiring layer 112 of the first wiring structure 110.

In an exemplary embodiment of the present inventive concept, the first element 180 may be a passive element. In an exemplary embodiment of the present inventive concept, the first element 180 may be a capacitor or a resistor of the passive elements. However, the present inventive concept is not limited thereto.

The first mold layer 130 may be formed on the first wiring structure 110. The first mold layer 130 may fill a space between the first wiring structure 110 and the second wiring structure 210. Accordingly, the first mold layer 130 may cover and protect at least a part of the first wiring structure 110, the first semiconductor chip 150, and the insulating member 250.

The first mold layer 130 may include, for example, an insulating polymer material such as EMC (epoxy molding compound). The first mold layer 130 may include a thermosetting resin such as an epoxy resin, a thermoplastic resin such as polyimide, or a resin in which a reinforcing material such as a filler is included therein, for example, ABF, FR-4, BT resin, or the like.

The filler may utilize at least one or more of silica (SiO₂), alumina (Al₂O₃), silicon carbide (SiC), barium sulfate (BaSO₄), talc, mud, mica powder, aluminum hydroxide (Al(OH)₃), magnesium hydroxide (Mg(OH)₂), calcium carbonate (CaCO₃), magnesium carbonate (MgCO₃), magnesium oxide (MgO), boron nitride (BN), aluminum borate (AlBO₃), barium titanate (BaTiO₃), and/or calcium zirconate (CaZrO₃). However, the material of the filler is not limited thereto.

Referring to FIG. 6, the semiconductor package according to an exemplary embodiment of the present inventive concept further includes a second semiconductor package 1000B including a second semiconductor chip 350 mounted on a third wiring structure 310, and the second semiconductor package 1000B is disposed on the first semiconductor package 1000A.

The third wiring structure 310 may be placed on the upper side of the second wiring structure 210. The third wiring structure 310 may be a wiring structure for packaging. For example, the third wiring structure 310 may be a printed circuit board (PCB), a ceramic wiring structure, or the like. In addition, the third wiring structure 310 may be a wiring structure for a wafer level package (WLP) fabricated at the wafer level. The third wiring structure 310 may include a lower side and an upper side opposite to each other.

The third wiring structure 310 includes an insulating layer 311 and a wiring layer 312. The wiring layer 312 may include a wiring via 313a that connects between the wiring pads 312a and between the wiring pad 312a and the second semiconductor chip 350. For example, the wiring vias 313a are connected to the semiconductor chip 350, and the wiring vias 313a connect the wiring pads 312a to each other.

The insulating layer 311 may be, for example, a printed circuit board (PCB) or a ceramic substrate. However, the present inventive concept is not limited thereto.

When the insulating layer 311 is a printed circuit board, the insulating layer 311 may be made of at least one of phenol resin, epoxy resin, and polyimide. For example, the insulating layer 311 may include at least one of FR-4, tetrafunctional epoxy, polyphenylene ether, epoxy/polyphenyl oxide, BT (bismaleimide triazine), thermount, cyanate ester, polyimide, and liquid crystal polymer.

The surface of the insulating layer 311 may be covered with a solder resist. For example, the solder resist may be formed at the bottom of the insulating layer 311. However, the present inventive concept is not limited thereto.

Although the insulating layer 311 and the wiring layer 312 are each shown as two layers, this is merely an example. For example, the insulating layer 311 and the wiring layer 312 may be made up of two or more multiple layers.

The second connecting structure 240 may be interposed between the second wiring structure 210 and the third wiring structure 310. The second connecting structure 240 may come into contact with the upper side of the second wiring structure 210 and the lower side of the third wiring structure 310. The second connecting structure 240 may electrically connect the second wiring structure 210 and the third wiring structure 310 to each other. For example, the second connecting structure 240 may be connected to the first wiring pad 212a of the second wiring structure 210 and the wiring pad 312a of the third wiring structure 310.

The second connecting structure 240 may have, for example, but is not limited to, a spherical shape or an elliptical spherical shape. Although the second connecting structure 240 may include, for example, at least one of tin (Sn), indium (In), lead (Pb), zinc (Zn), nickel (Ni), gold (Au), silver (Ag), copper (Cu), antimony (Sb), bismuth (Bi), and combinations thereof, the present inventive concept is not limited thereto.

The second semiconductor chip 350 may be placed on the third wiring structure 310. For example, the second semiconductor chip 350 may be mounted on the upper side of the third wiring structure 310. The second semiconductor chip 350 may be an integrated circuit (IC) in which hundreds to millions or more of semiconductor elements are integrated.

In an exemplary embodiment of the present inventive concept, the first semiconductor chip 150 may be a logic chip such as an application processor (AP), and the second semiconductor chip 350 may be a memory chip such as a volatile memory (e.g., DRAM) or a non-volatile memory (e.g., ROM or a flash memory).

Although only one second semiconductor chip 350 is shown as being formed on the third wiring structure 310, this is merely an example. For example, a plurality of second semiconductor chips 350 may be formed side by side on the third wiring structure 310, or a plurality of second semiconductor chips 350 may be sequentially stacked on the third wiring structure 310.

In an exemplary embodiment of the present inventive concept, the second semiconductor chip 350 may be mounted on the third wiring structure 310 by a flip chip bonding method. For example, the first bump 360 may be formed between the upper side of the third wiring structure 310 and the lower side of the second semiconductor chip 350. The first bump 360 may electrically connect the third wiring structure 310 and the second semiconductor chip 350 to each other.

The first bump 360 may include, for example, a second pillar layer 362 and a second solder layer 364.

The second pillar layer 362 may protrude from the lower side of the first semiconductor chip 150. The second pillar layer 362 may include, for example, but is not limited to, copper (Cu), copper alloy, nickel (Ni), palladium (Pd), platinum (Pt), gold (Au), cobalt (Co) and combinations thereof.

The second solder layer 364 may connect the second pillar layer 362 and the first wiring structure 110 to each other. For example, the second solder layer 364 may be electrically connected to the wiring pad 312a. The second solder layer 364 may have, for example, but is not limited to, a spherical shape or an elliptical spherical shape. The second solder layer 364 may include, for example, but is not limited to, tin (Sn), indium (In), bismuth (Bi), antimony (Sb), copper (Cu), silver (Ag), zinc (Zn), lead (Pb) and combinations thereof.

In an exemplary embodiment of the present inventive concept, a fourth mold layer 330 may be formed on the third wiring structure 310. The fourth mold layer 330 may cover and protect the third wiring structure 310, the second semiconductor chip 350, and the first bump 360. The fourth mold layer 330 may include, for example, but is not limited to, an insulating polymeric material, such as EMC.

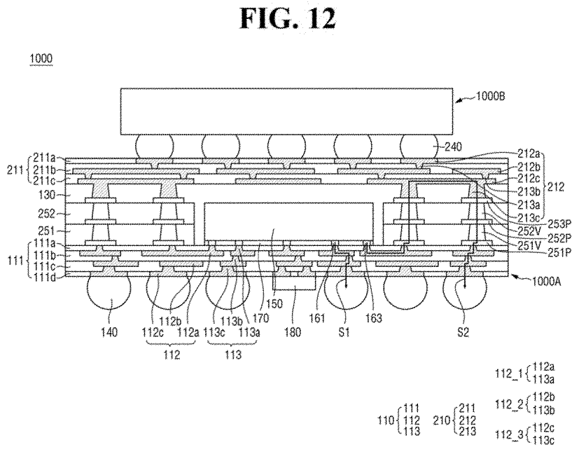

Hereinafter, a semiconductor package according to an exemplary embodiment of the present inventive concept will be described with reference to FIG. 12. For convenience of explanation, differences from the semiconductor package shown in FIGS. 1 to 11 will be mainly described. In addition, in the following exemplary embodiments of the present inventive concept, a description of substantially the same configuration and elements as that of the previously described embodiment may be omitted or simplified.

FIG. 12 is a schematic cross-sectional view of a semiconductor package taken along I-I′ of FIG. 4 according to an exemplary embodiment of the present inventive concept.

Referring to FIG. 12, the second signal pattern S2 may form an electrical path that goes through the first to third wiring layers 112_1, 112_2 and 112_3 of the first wiring structure 110, through the insulating member 250 and the second wiring structure 210.

The second signal pattern S2 may transmit the signal from the second connecting pad 163 to the first wiring via 113a, the first wiring pad 112a, the first wiring via 113a, the first connecting pad 251P, the first connecting via 251V, the second connecting pad 252P, and the second wiring structure 210. In addition, the second signal pattern S2 may redistribute the second connecting pad 163 to the first connecting structure 140 through the electrical path which goes through the insulating member 250, the third wiring pad 212c, the first wiring layer 112_1, the second wiring layer 112_2, and the third wiring layer 112_3 in order.

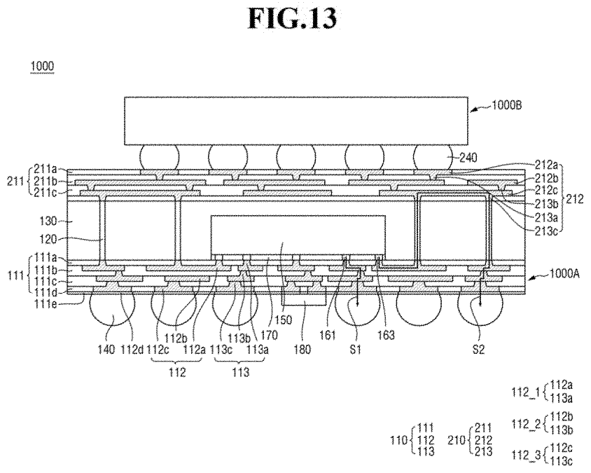

Hereinafter, a semiconductor package according to an exemplary embodiment of the present inventive concept will be described with reference to FIG. 13. For convenience of explanation, differences from the semiconductor packages shown in FIGS. 1 to 11 will be mainly described. In addition, in the following exemplary embodiments of the present inventive concept, a description of substantially the same configuration and elements as that of the previously described embodiment may be omitted or simplified.

FIG. 13 is a schematic cross-sectional view of a semiconductor package taken along I-I′ of FIG. 4 according to an exemplary embodiment of the present inventive concept.

The first wiring structure 110 may further include a fifth insulating layer 111e placed below the third wiring layer 112_3. A lower pad 112d is attached to the fifth insulating layer 111e, and may connect the first to third wiring layers 112_1, 112_2 and 112_3 to the first connecting structure 140. The lower pad 112d may be exposed by the fifth insulating layer 111e.

A first through via 120 may be interposed between the first wiring structure 110 and the second wiring structure 210. The first through via 120 may come into contact with the upper side of the first wiring structure 110 and the lower side of the second wiring structure 210. The first through via 120 may electrically connect the first wiring structure 110 and the second wiring structure 210 to each other. For example, the first through via 120 may be connected to the first wiring via 113a of the first wiring structure 110 and the third wiring via 213c of the second wiring structure 210.

The second signal pattern S2 may form an electrical path that goes through the first wiring layer 112_1, through the first through via 120 and the second wiring structure 210.

The second signal pattern S2 may transmit the signal from the second connecting pad 163 to the first wiring via 113a, the first wiring pad 112a, the first wiring via 113a, the first through via 120, and the second wiring structure 210. In addition, the second signal pattern S2 may redistribute the second connecting pad 163 to the first connecting structure 140 through the electrical path that goes through the first through via 120, the third wiring pad 212c, the first wiring layer 112_1, the second wiring layer 112_2, and the third wiring layer 112_3 in order via.

The first through via 120 may have, for example, but is not limited to, a shape that penetrates the first mold layer 130. The first through via 120 may include, for example, but is not limited to, tin (Sn), indium (In), bismuth (Bi), antimony (Sb), copper (Cu), silver (Ag), zinc (Zn), lead (Pb) and combinations thereof.

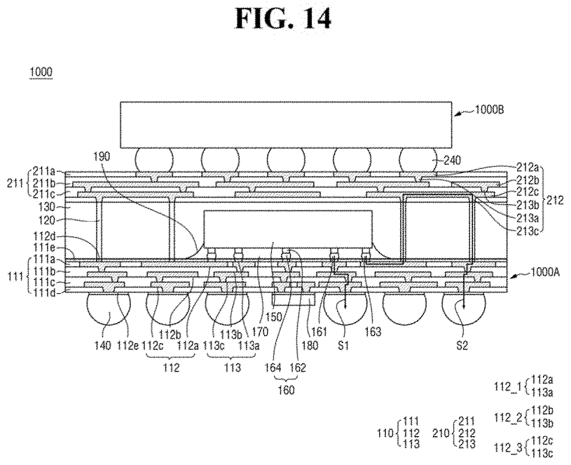

Hereinafter, a semiconductor package according to an exemplary embodiment of the present inventive concept will be described with reference to FIG. 14. For convenience of explanation, differences from the semiconductor packages shown in FIGS. 1 to 11 will be mainly described. In addition, in the following exemplary embodiments of the present inventive concept, a description of substantially the same configuration and elements as that of the previously described embodiment may be omitted or simplified.

FIG. 14 is a schematic cross-sectional view of a semiconductor package taken along I-I′ of FIG. 4 according to an exemplary embodiment of the present inventive concept.

The first wiring structure 110 may further include a fifth insulating layer 111e placed above the first wiring layer 112_1. An upper pad 112d is attached to the fifth insulating layer 111e, and may connect the first to third wiring layers 112_1, 112_2 and 112_3 to the first through via 120, and connect the first to third wiring layers 112_1, 112_2 and 112_3 to the first semiconductor chip 150. The upper pad 112d may be exposed by the fifth insulating layer 111e.

The first through via 120 may be interposed between the first wiring structure 110 and the second wiring structure 210. The first through via 120 may come into contact with the upper side of the first wiring structure 110 and the lower side of the second wiring structure 210. The first through via 120 may electrically connect the first wiring structure 110 and the second wiring structure 210 to each other. For example, the first through via 120 may come into contact with the upper pad 112d of the first wiring structure 110 and the third wiring via 213c of the second wiring structure 210.

The connecting pad 160 may include, for example, a first pillar layer 162 and a first solder layer 164.

The first pillar layer 162 may protrude from the lower side of the first semiconductor chip 150. The first pillar layer 162 may include, for example, but is not limited to, copper (Cu), copper alloy, nickel (Ni), palladium (Pd), platinum (Pt), gold (Au), cobalt (Co) and combinations thereof.

The first solder layer 164 may connect the first pillar layer 162 and the first wiring structure 110 to each other. For example, the first solder layer 164 may be connected to the upper pad 112d. The first solder layer 164 may have, for example, but is not limited to, a spherical shape or an elliptical spherical shape. The first solder layer 164 may include, for example, but is not limited to, tin (Sn), indium (In), bismuth (Bi), antimony (Sb), copper (Cu), silver (Ag), zinc (Zn), lead (Pb) and combinations thereof.

The second signal pattern S2 may form an electrical path that goes through the first wiring layer 112_1, through the first through via 120 and the second wiring structure 210.

The second signal pattern S2 may transmit the signal from the second connecting pad 163 to the upper pad 112d, the first wiring via 113a, the first wiring pad 112a, the first wiring via 113a, the first through via 120, and the second wiring structure 210. In addition, the second signal pattern S2 may redistribute the second connecting pad 163 to the first connecting structure 140 through the electrical path which goes through the first through via 120, the third wiring pad 212c, the first wiring layer 112_1, the second wiring layer 112_2, and the third wiring layer 112_3 in order.

The first through via 120 may have, for example, but is not limited to, a shape that penetrates the first mold layer 130. The first through via 120 may include, for example, but is not limited to, tin (Sn), indium (in), bismuth (Bi), antimony (Sb), copper (Cu), silver (Ag), zinc (Zn), lead (Pb) and combinations thereof.

A lower pad 112e is attached to the fourth insulating layer 111d, and may connect the first to third wiring layers 112_1, 112_2 and 112_3 to the first connecting structure 140.

An underfill material 190 may cover the lower side and a part of the side faces of the first semiconductor chip 150, and the side faces of the first connecting pad 160. The underfill material 190 may prevent the first semiconductor chip 150 from cracking or the like, by fixing the first semiconductor chip 150 onto the first wiring structure 110. The underfill material 190 may include, for example, an insulating polymer material such as EMC (epoxy molding compound). However, the material of the underfill material 190 is not limited thereto, and may include a material different from those of the first to third mold layers 130, 251 and 252.

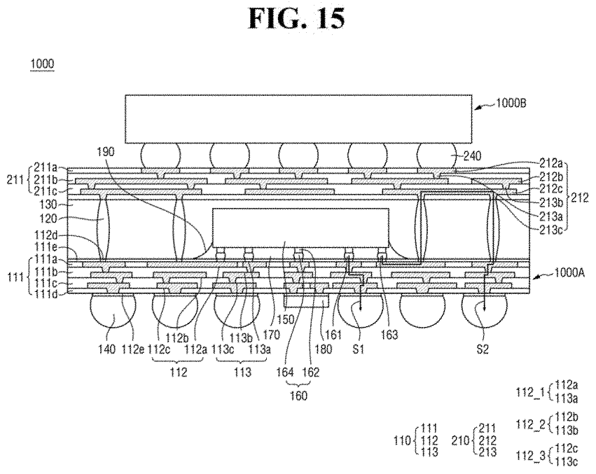

Hereinafter, a semiconductor package according to an exemplary embodiment of the present inventive concept will be described with reference to FIG. 15. For convenience of explanation, differences from the semiconductor packages shown in FIGS. 1 to 11 will be mainly described. In addition, in the following exemplary embodiments of the present inventive concept, a description of substantially the same configuration and elements as that of the previously described embodiment may be omitted or simplified.

FIG. 15 is a schematic cross-sectional view of a semiconductor package taken along I-I′ of FIG. 4 according to an exemplary embodiment of the present inventive concept.

The first connecting member 120 may be interposed between the first wiring structure 110 and the second wiring structure 210. The first connecting member 120 may come into contact with the upper side of the first wiring structure 110 and the lower side of the second wiring structure 210. The first connecting member 120 may electrically connect the first wiring structure 110 and the second wiring structure 210 to each other. For example, the first connecting member 120 may come into contact with the upper pad 112d of the first wiring structure 110 and the third wiring via 213c of the second wiring structure 210.

The first wiring structure 110 may further include a fifth insulating layer 111e placed above the first wiring layer 112_1. The upper pad 112d is attached to the fifth insulating layer 111e, and may connect the first to third wiring layers 112_1, 112_2 and 112_3 to the first connecting member 120, and connect the first to third wiring layers 112_1, 112_2 and 112_3 and the first semiconductor chip 150 to each other.

The connecting pad 160 may include, for example, a first pillar layer 162 and a first solder layer 164.

The first pillar layer 162 may protrude from the lower side of the first semiconductor chip 150. The first pillar layer 162 may include, for example, but is not limited to, copper (Cu), copper alloy, nickel (Ni), palladium (Pd), platinum (Pt), gold (Au), cobalt (Co) and combinations thereof.

The first solder layer 164 may connect the first pillar layer 162 and the first wiring structure 110 to each other. For example, the first solder layer 164 may be connected to the upper pad 112d. The first solder layer 164 may have, for example, but is not limited to, a spherical shape or an elliptical spherical shape. The first solder layer 164 may include, for example, but is not limited to, tin (Sn), indium (In), bismuth (Bi), antimony (Sb), copper (Cu), silver (Ag), zinc (Zn), lead (Pb) and combinations thereof.

The second signal pattern S2 may form an electrical path that goes through the first wiring layer 112_1, through the first connecting member 120 and the second wiring structure 210.

The second signal pattern S2 transmit the signal from the second connecting pad 163 to the upper pad 112d, the first wiring via 113a, the first wiring pad 112a, the first wiring via 113a, the first connecting member 120, and the second wiring structure 210. In addition, the second signal pattern S2 may redistribute the second connecting pad 163 to the first connecting structure 140 through the electrical path that goes through the first connecting member 120, the third wiring pad 212c, the first wiring layer 112_1, the second wiring layer 112_2, and the third wiring layer 112_3 in order via.

The first connecting member 120 may have, for example, but is not limited to, a spherical shape or an elliptical spherical shape. The first connecting member 120 may include, for example, but is not limited to, tin (Sn), indium (In), bismuth (Bi), antimony (Sb), copper (Cu), silver (Ag), zinc (Zn), lead (Pb) and combinations thereof.

The second wiring structure 210 may be stacked on the first wiring structure 110, for example, by a TC (thermal compression) bonding method of applying heat at the same time while pressing the upper side of the second wiring structure 210 using a bonding mechanism. However, the present inventive concept is not limited thereto.

The lower pad 112e is attached to the fourth insulating layer 111d, and may connect the first to third wiring layers 112_1, 112_2 and 112_3 to the first connecting structure 140.

The underfill material 190 may cover the lower side and a part of the side faces of the first semiconductor chip 150, and the side faces of the first connecting pad 160. The underfill material 190 may prevent the first semiconductor chip 150 from cracking or the like, by fixing the first semiconductor chip 150 onto the first wiring structure 110. The underfill material 190 may include, for example, an insulating polymer material such as EMC (epoxy molding compound). However, the material of the underfill material 190 is not limited thereto, and may include a material different from those of the first to third mold layers.

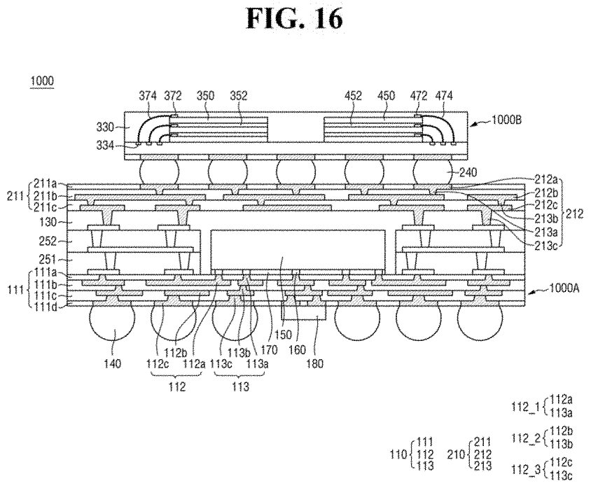

Hereinafter, a semiconductor package according to an exemplary embodiment of the present inventive concept will be described referring to FIG. 16. For convenience of explanation, differences from the semiconductor packages shown in FIGS. 1 to 11 will be mainly described. In addition, in the following exemplary embodiments of the present inventive concept, a description of substantially the same configuration and elements as that of the previously described embodiment may be omitted or simplified.

FIG. 16 is a schematic cross-sectional view of a semiconductor package taken along I-I′ of FIG. 4 according to an exemplary embodiment of the present inventive concept.

Referring to FIG. 16, the semiconductor package according to an exemplary embodiment of the present inventive concept may include second semiconductor chips 350 and third semiconductor chips 450. The second semiconductor chips 350 and the third semiconductor chips 450 may form a stacked structure. The number of stacked structures and the number of semiconductor chips constituting the stacked structures may vary.

For example, the first semiconductor chip 150 may be a logic chip, and the second semiconductor chips 350 and the third semiconductor chips 450 may be memory chips. However, the present inventive concept is not limited thereto.

The second semiconductor chips 350 may be mounted on the third wiring structure 310 by a first adhesive layer 352. The third semiconductor chips 450 may be mounted on the third wiring structure 310 by a second adhesive layer 452. The first adhesive layer 352 and the second adhesive layer 452 may include, for example, but are not limited to, at least one of a liquid epoxy, an adhesive tape, a conductive medium, and a combination thereof.

The second semiconductor chips 350 may be electrically connected to the third wiring structure 310 (see, e.g., FIG. 6) by a first bonding wire 374. For example, the first bonding wire 374 may connect the first chip pad 372 to the third upper pad 334 of the third wiring structure 310. The third semiconductor chips 450 may be electrically connected to the third wiring structure 310 by a second bonding wire 474. For example, the second bonding wire 474 may connect the second chip pad 472 to the third upper pad 334 of the third wiring structure 310. However, the present inventive concept is not limited thereto, and the second semiconductor chips 350 and/or the third semiconductor chips 450 may be electrically connected to the third upper pad 334 by, for example, a bonding tape or the like.

While the present inventive concept has been described with reference to exemplary embodiments thereof, it will be understood by those of ordinary skill in the art that various changes in form and details may be made thereto without departing from the spirit and scope of the present invention.

What is claimed is:

1. A semiconductor package comprising:
a first wiring structure including a first wiring layer, and a second wiring layer disposed on the first wiring layer, and connected to a first connecting structure placed disposed on the first wiring layer;
a first semiconductor chip disposed on the first wiring structure and connected to the first wiring structure through a first connecting pad disposed on a first side of the first semiconductor chip;
a second wiring structure disposed on the first semiconductor chip; and
an insulating member disposed between the first and second wiring structures,
wherein the first wiring structure further includes a first signal pattern that is electrically connected to the first connecting pad, and
the first signal pattern redistributes the first connecting pad to the first connecting structure via the insulating member.

2. The semiconductor package of claim 1, wherein the insulating member further includes a connecting via that penetrates at least a part of the insulating member, and
the first signal pattern forms an electrical path which goes through the first wiring layer and the connecting via.

3. The semiconductor package of claim 1, wherein the first signal pattern redistributes the first connecting pad to the first connecting structure through an electrical path which goes through the second wiring layer, the insulating member and the first wiring layer.

4. The semiconductor package of claim 1, wherein the first wiring structure further includes a second signal pattern which has a path different from the first signal pattern, is electrically connected to a second connecting pad placed on the first side of the first semiconductor chip, and redistributes the second connecting pad to the first connecting structure.

5. The semiconductor package of claim 4, wherein the first signal pattern has an electrical path which increases by a distance corresponding to a thickness of the insulating member as compared to that of the second signal pattern.

6. The semiconductor package of claim 4, wherein the second signal pattern redistributes the second connecting pad to the first connecting structure through an electrical path which goes through the second wiring layer and the first wiring layer in that order from the second connecting pad.

7. The semiconductor package of claim 1, wherein the insulating member includes:
a first mold layer disposed on the first wiring structure;
a second mold layer on the first mold layer;
a first connecting via penetrating the first mold layer;
a second connecting via penetrating the second mold layer; and
a connecting pad electrically connected to the first and second connecting vias.

8. The semiconductor package of claim 7, wherein the first signal pattern redistributes the first connecting pad to the first connecting structure through an electrical path which goes through the second wiring layer, the first connecting via, the connecting pad, the second wiring layer and the first wiring layer in that order from the first connecting pad.

9. The semiconductor package of claim 1, wherein the first wiring structure further includes a third wiring layer disposed between the first and second wiring layers, and
the first wiring structure further includes:
a first wiring via connecting the first semiconductor chip and the second wiring layer to each other;
a second wiring via connecting the second wiring layer and the third wiring layer to each other; and
a third wiring via connecting the third wiring layer and the first wiring layer to each other.

10. The semiconductor package of claim 1, wherein the first signal pattern forms an electrical path which goes through the first wiring layer, through the insulating member and the second wiring structure.

11. A semiconductor package comprising:
a first wiring structure including a first wiring layer and a second wiring layer disposed on the first wiring layer, and connected to a first connecting structure disposed below the first wiring layer;
a first semiconductor chip disposed on the first wiring structure and connected to the first wiring structure through a first connecting pad disposed on a first side of the first semiconductor chip;
a second wiring structure disposed on the first semiconductor chip; and
a mold layer disposed between the first and second wiring structures,
wherein the first wiring structure includes a first signal pattern that is electrically connected to the first connecting pad, and
the first signal pattern redistributes the first connecting pad to the first connecting structure via the mold layer and the second wiring structure.

12. The semiconductor package of claim 11, further comprising:
a through via penetrating the mold layer and connecting the first and second wiring structures to each other,
wherein the first signal pattern forms an electrical path which goes through the first wiring layer and the through via.

13. The semiconductor package of claim 11, wherein the first signal pattern redistributes the first connecting pad to the first connecting structure through an electrical path which goes through the second wiring layer, the mold layer, the second wiring structure, and the first wiring layer in that order from the first connecting pad.

14. The semiconductor package of claim 11, wherein the first wiring structure further includes a second signal pattern which is electrically connected to a second connecting pad disposed on a first side of the first semiconductor chip and has a path different from that of the first signal pattern.

15. The semiconductor package of claim 14, wherein the first signal pattern has an electrical path which increases by a distance corresponding to a thickness of the mold layer as compared with that of the second signal pattern.

16. The semiconductor package of claim 14, wherein the second signal pattern redistributes the second connecting pad to the first connecting structure through an electrical path which goes through the second wiring layer and the first wiring layer.

17. The semiconductor package of claim 11, wherein the mold layer covers at least a portion of the first semiconductor chip.

18. A semiconductor package comprising:
a first semiconductor package; and
a second semiconductor package disposed on the first semiconductor package,
wherein the first semiconductor package includes:
a first wiring structure including a first wiring layer and a second wiring layer disposed on the first wiring layer, and connected to a first connecting structure disposed below the first wiring layer;
a first semiconductor chip disposed on the first wiring structure and connected to the first wiring structure through a first connecting pad disposed on a first side of the first semiconductor chip;
a second wiring structure disposed on the first semiconductor chip; and
an insulating member disposed between the first and second wiring structures and including a connecting via,
wherein the first wiring structure includes a first signal pattern electrically connected to the first connecting pad,
the first signal pattern redistributes the first connecting pad to the first connecting structure via the connecting via, and
the second semiconductor package includes a second semiconductor chip mounted on a third wiring structure that is disposed on the first semiconductor package.

19. The semiconductor package of claim 18, wherein the first signal pattern redistributes the first connecting pad to the first connecting structure through an electrical path which goes through the second wiring layer, the insulating member, and the first wiring layer in that order from the first connecting pad.

20. The semiconductor package of claim 18, wherein the first wiring structure further includes a second signal pattern which is electrically connected to a second connecting pad disposed on the first side of the first semiconductor chip, and has a path different from that of the first signal pattern, and
the first signal pattern has an electrical path which increases by a distance corresponding to a thickness of the connecting via, as compared with that of the second signal pattern.
